(19) United States
(12) Patent Application Publication
(10) Pub. No.: US 2024/0215461 A1
(43) Pub. Date: Jun. 27, 2024

(54) METHOD FOR MANUFACTURING A PHASE CHANGE MEMORY DEVICE

(71) Applicant: COMMISSARIAT A L'ENERGIE ATOMIQUE ET AUX ENERGIES ALTERNATIVES, Paris (FR)

(72) Inventors: Guillaume BOURGEOIS, Grenoble Cedex 09 (FR); Gabriele NAVARRO, Grenoble Cedex 09 (FR)

(73) Assignee: COMMISSARIAT A L'ENERGIE ATOMIQUE ET AUX ENERGIES ALTERNATIVES, Paris (FR)

(21) Appl. No.: 18/390,103

(22) Filed: Dec. 20, 2023

(30) Foreign Application Priority Data
Dec. 21, 2022 (FR) 22 14054

(51) Int. Cl. H10N 70/20; G11C 13/00; H10N 70/00

(52) U.S. Cl. CPC H10N 70/231; G11C 13/0004; H10N 70/043; H10N 70/063; H10N 70/841; H10N 70/882; H10N 70/883

(57) ABSTRACT

A phase change memory device comprising a stack comprising a memory point. The memory point comprises, stacked in a vertical direction (Z), a lower electrode, a chalcogenide section disposed on the lower electrode, and an upper electrode disposed on the chalcogenide section. The memory point has a side surface and an upper face, and comprises an encapsulation layer disposed in contact with the side surface and the upper face, and a doped portion extending from the side surface and inside the chalcogenide section, along its entire height. The chalcogenide section also has a non-doped portion having a zero doping or a doping less than the doping of the doped portion and extending from the doped portion up to the center of the chalcogenide section.

### TECHNICAL FIELD

The present invention relates to the field of phase change memory devices. It has a particularly advantageous application in the field of memory devices with the basis of at least one chalcogenide layer, for example, germanium-, selenium and tellurium-based (GeSbTe, also called GST material).

### PRIOR ART

Memory devices represent crucial challenges in numerous applications, for example for the memory type commonly called Storage Class Memory (SCM), embedded memories for motor vehicles, or neuromorphic applications. In this context, resistive memories represent very good candidates for supporting or replacing Flash memory. Resistive memories indeed have significant advantages in terms of speed and scaling, i.e. reducing dimensions of the memory unit cell, and of the distance between two memory points, which has the effect of increasing the density of memory points in memory arrays. Among resistive memories, phase change memories (commonly abbreviated to PCM) represent the non-volatile resistive memory technology among the most mature and at an advanced development and production stage.

Phase change memories typically comprise two programming states obtained from a layer with the basis of a chalcogenide material forming a so-called “memory” layer and having an amorphous state and a crystalline state:
“reset” or equally HRS (High Resistive State) programming, which is based on the melting of all or some of the chalcogenide layer, during an electrical pulse making it possible to reach the melting point of the material by Joule effect. Then, the melted part of the chalcogenide material is frozen in an amorphous state by sudden cooling, obtained by rapid reduction of the current. The amorphous state of the chalcogenide material is barely electrically conductive. Reset programming makes it possible to store the “0” information, with the storage of an increase resistance in the PCM device.
“set”, or equally LRS (Low Resistive State) programming, which is based on a partial or total melting of the chalcogenide material during an electrical pulse. Then, the chalcogenide material is crystallised by a gradual cooling obtained by gradual reduction of the current. The crystalline state of the chalcogenide material is a better electrical conductor than the amorphous state. Set programming makes it possible to store the “1” information, with the storage of a low resistance in the PCM device.

The memory layer can further be completed by a second so-called “selective” chalcogenide layer, incorporated in a selector or switch module of the PCM device (commonly called ovonic threshold switch, OTS). The second chalcogenide layer in the amorphous state, has different electrical conductivity states with the application of a threshold voltage and an initialisation voltage. Beyond the threshold voltage, the second chalcogenide layer has a low resistivity, enabling the passage of a high electrical current flow. The electrical current makes it possible to program and to read the PCM device selected in a network, without unwanted programming of the adjacent devices. The threshold voltage is the switching voltage of the selective layer to enable the passage of the current. The threshold voltage can be used to differentiate the set state and the reset state. The initialisation voltage is the threshold voltage necessary for the first switching, typically greater than the subsequent threshold voltages.

Among the requested specifications, according to the application, a stability of the high temperature amorphous phase will be sought, a reliability with a programming error rate typically less than 1 ppm (10⁻⁶), an endurance typically greater than 10⁹ cycles and/or rapid crystallisation speeds.

However, certain steps of manufacturing a PCM device have a negative impact of its performance. In particular, the etching of patterning of the PCM device affects the composition of the chalcogenide layers and can generate an undesired recrystallisation of these layers, an acceleration of the segregation phenomena and a poor functionality of the PCM device for critical dimensions which are too small.

Even by encapsulating the PCM device, it is observed that this has a degraded performance. In particular, the presence of an oxygen peak is frequently noted at the flanks of the device. Known solutions therefore do not propose a satisfactory solution for reducing the dimension of a memory point without significantly degrading its performance.

An aim of the present invention is therefore to propose a solution improving the properties of a phase change memory device.

Other aims, features and advantages of the present invention will appear upon examining the description below and the accompanying drawings. It is understood that other advantages can be incorporated.

### SUMMARY

To achieve this aim, a first aspect of the invention relates to a phase change memory device comprising a stack comprising a memory point, the memory point comprising, stacked in a so-called vertical direction:
i. a lower electrode formed in a lower layer,
ii. at least one so-called chalcogenide section formed in at least one chalcogenide layer, disposed on the lower electrode,
iii. an upper electrode formed in an upper layer and disposed on the at least one chalcogenide section, the memory point having a side surface and an upper face.

The memory point also comprises an encapsulation layer encapsulating the memory point and disposed in contact with the side surface and with the upper face. The memory point has at least one so-called doped portion, extending from the side surface and inside the chalcogenide section, and having a doping with the basis of at least one species, called doping species, chosen from among the following species: carbon, fluorine, nitrogen, indium, arsenic, aluminium, germanium, silicon, chlorine and boron. The doped portion extends, in the so-called vertical direction along the entire height of the chalcogenide section. The chalcogenide section has a so-called non-doped portion, having a zero doping, or doping less than the doping of the doped portion in said doping species, the non-doped portion extending from the doped portion and to a centre of the chalcogenide section.

A second aspect of the invention relates to a method for manufacturing a phase change memory device comprising the following steps:
a provision of a stack having an upper face, the stack comprising, stacked in a so-called vertical direction:
   i. a lower layer,
   ii. at least one so-called chalcogenide layer with the basis of at least one chemical element of the chalcogenide family,
   iii. an upper layer,
a patterning etching of the substrate from its upper face, the patterning etching extending until in at least one part of the lower layer and making it possible to form a memory point comprising:
   i. a lower electrode formed in the lower layer,
   ii. at least one so-called chalcogenide section formed in the at least one chalcogenide layer, disposed on the lower electrode,
   iii. an upper electrode formed in the upper layer and disposed on the at least one chalcogenide section, the memory point having a side surface and an upper face.
a formation of an encapsulation layer encapsulating the memory point and disposed in contact with the side surface and with the upper face of the memory point,
an ion implantation of a so-called doping species in the at least one chalcogenide section through the encapsulation layer, the ion implantation being achieved in an implantation direction forming a so-called implantation angle θᵢₘₚₗ with the vertical direction, with θᵢₘₚₗ≥225°,
the ion implantation being configured so as to dope at least one portion of the chalcogenide section, the portion extending from the side surface.

Following the patterning etching of the stack to form the memory point and following the encapsulation of the latter, the memory point and, in particular, the chalcogenide section have numerous defects. Among these, this in particular includes structural defects caused by the patterning etching, and an oxidation of the chalcogenide species due to the unavoidable venting of the memory point before its encapsulation. These etching and encapsulation steps are however extremely common, even unavoidable during the production of memory devices.

The implantation such as described above makes it possible to remove or, at the very least, reduce the quantity of these defects and, in particular, make the interface reliable between the chalcogenide section and the encapsulation layer. It makes it possible, in particular, to destroy the oxide bonds formed with the chalcogenide species and to form instead of bonds between the chalcogenide species and the doping species, for example, Ge—C bonds.

The implantation proposed from the side surface of the memory point also makes it possible to improve the property of the interface between the chalcogenide section and the encapsulation layer, making it possible to avoid the interfering degeneration effects of the chalcogenide species at said interface, and to improve the adherence between the memory point and the encapsulation layer.

Thanks to the inclination of the implantation, the method enables the treatment of the interface between the memory point and the encapsulation layer without modification of the chalcogenide material, which a vertical implantation does not enable.

The implantation proposed also has the advantage of reducing the stress of the amorphous chalcogenide section at the interface with the encapsulation layer. This has the direct benefit of relaxing the stresses and therefore limiting the quantity of structural defects which could appear, as well as a better robustness of the device. This also has a positive impact on the service life of the device, in particular, in terms of endurance.

In the scope of the present invention, the doping of the chalcogenide layer is done by ion implantation on an already-formed chalcogenide layer. The ion implantation enables a better control of the location of the doping species in the chalcogenide layer, and this, in particular for lower concentrations than by co-sputtering.

During the development of the invention, it has further been highlighted that, surprisingly, the ion implantation induces a structural redistribution of the chalcogenide layer (by the passage of ions and their implantation), which makes it possible to improve its properties. The performance of the PCM device is thus improved. The programming of the SET state and the endurance of the PCM device can, in particular, be improved.

This solution clearly stands out from solutions implementing a deposition by co-sputtering, which, on the contrary, encourage to adapt the deposition parameters by sputtering to improve the properties of a carbon-doped PCM device.

The advantages described for the method for manufacturing the device extend to the device in itself, which, in particular, has a good interface quality between the memory point and the encapsulation layer.

### BRIEF DESCRIPTION OF THE FIGURES

The aims, objective, as well as the features and advantages of the invention will emerge best from the detailed description of an embodiment of the latter, which is illustrated by the following accompanying drawings, wherein:

FIG. 1 represents a cross-sectional view in scanning electron microscopy illustrating, according to an example, the placement of a PCM device between the metal levels in the production back-end (of line).

FIG. 2 represents a perspective diagram of a memory point according to an example of an embodiment.

FIGS. 3A to 3I represent a first embodiment of the method according to the invention.

FIG. 3A illustrates the provision of a stack comprising a lower layer, a chalcogenide layer and an upper layer.

FIG. 3B illustrates the formation of an etching mask on the upper face of the stack.

FIG. 3C represents the formation of openings in the etching mask.

FIG. 3D illustrates the patterning etching of the stack through the etching mask, making it possible to obtain a memory point comprising a lower electrode, a chalcogenide section and an upper electrode.

FIG. 3E illustrates the removal of the etching mask.

FIG. 3F represents a step of encapsulating the memory point by an encapsulation layer.

FIG. 3G illustrates a step of implanting the memory point, and quite specifically, the chalcogenide section through the encapsulation layer.

FIG. 3H represents the memory device after implantation.

FIG. 3I represents a detail of FIG. 3F, showing, in particular, the chalcogenide section including its doped portion.

FIGS. 4A to 4E represent a second embodiment of the method according to the invention.

FIG. 4A illustrates the provision of a stack comprising a lower layer, a first chalcogenide layer, an intermediate layer, a second chalcogenide layer and an upper layer.

FIG. 4B illustrates the memory point obtained after a patterning etching of the stack illustrated in FIG. 4A. The memory point comprises a lower electrode, a first chalcogenide section, an intermediate electrode, a second chalcogenide section and an upper electrode.

FIG. 4C represents a step of encapsulating the memory point by an encapsulation layer.

FIG. 4D illustrates a step of implanting the memory point, and quite specifically, chalcogenide sections through the encapsulation layer.

FIG. 4E represents the memory device after implantation.

FIGS. 5A, 5B and 5C represent diagrams, respectively as a perspective, as a front view and as a top view, of a PCM device according to an example of an embodiment.

FIG. 6 is a graph illustrating the development of the concentration of different species in a wafer of the PCM device comprising a portion of the memory layer and of the encapsulation layer.

FIG. 7 is a graph illustrating the implantation profiles obtained for two different implantation energies in a wafer of the PCM device comprising a portion of the memory layer and of the encapsulation layer.

FIG. 8 is a graph illustrating the development of the resistivity of the memory layer of the memory device according to the temperature, for different implantation energy and implanted dose values.

FIG. 9 is a graph illustrating the density within the memory layer of the memory device and the impacted memory layer thickness for different implantation energies and implanted doses.

The drawings are given as examples and are not limiting of the invention. They constitute principle schematic representations intended to facilitate the understanding of the invention, and are not necessarily to the scale of practical applications. In particular, the dimensions are not representative of reality.

### DETAILED DESCRIPTION

Before starting a detailed review of embodiments of the invention, below optional features are stated, which can optionally be used in association or alternatively: Advantageously, 20≤θᵢₘₚₗ≤60°.

Preferably, the portion has, in all the directions of a transverse plane perpendicular to the vertical direction, a radial dimension l125 with l125≤20 nm, preferably l125: 10 nm. This makes it possible to avoid that the performance of the chalcogenide material is altered, or at the very least, altered in proportions which are too large.

Advantageously, l₁₂₅≥2 nm, preferably I₁₂₅≥5 nm.

According to an embodiment, the at least one chalcogenide section comprises a first chalcogenide section and a second chalcogenide section:
the first chalcogenide section is disposed on the lower electrode, and intended to form a so-called memory layer, and
the second chalcogenide section is intended to form a so-called selective layer, the second chalcogenide section being separated from the first chalcogenide section by an intermediate electrode, and
the ion implantation is configured such that the portion of the chalcogenide section extends into the first chalcogenide section and the second chalcogenide section.

According to an example, the implanted doping species is at least one from among carbon, fluorine, nitrogen, indium, arsenic, aluminium, germanium, silicon, chlorine and boron.

According to an example, during the ion implantation, the implantation energy is greater than or equal to 1 keV, preferably greater than or equal to 4 keV, preferably greater than or equal to 10 keV, for example, greater than or equal to 30 keV.

According to an example, during the ion implantation, a dose of implanted doping species Dᵢₘₚₗ greater than 10¹⁵ atoms/cm² is implanted.

According to an embodiment, it is considered that the atomic percentage (or atomic concentration) of the doping species in the doped portion of a given chalcogenide section corresponds to the maximum atomic percentage observed in this given chalcogenide section. According to a preferred embodiment, the atomic percentage in the non-doped portion is less than or equal to 30%, preferably 20%, even 10% of this maximum atomic percentage observed in the chalcogenide section.

According to an example, the doped portion has a gradient of doping species from its side surface to the non-doped portion.

According to an example, the atomic percentage of the doping species within the doped portion is substantially constant in the stack direction.

According to an example, the non-doped portion has an atomic concentration of doping species strictly less than 0.5%.

According to an example, the encapsulation layer is with the basis of at least one material taken from among: SiN, SiC and SiCN.

According to an example, the chalcogenide section comprises at least one chemical element from among germanium Ge, antimony Sb and tellurium Te.

According to an example, the first chalcogenide section, or memory layer, can be with the basis of or made of any material belonging to the ternary diagram of germanium Ge, antimony Sb and tellurium Te. For example, this material is chosen from among Ge1Sb2Te4, GeTe, Sb2Te3, Ge7Sb1Te2.

S According to an example, the second chalcogenide section, or selective layer, comprises at least one chemical element from among selenium, arsenic, sulphur, silicon and aluminium.

According to an example, the second chalcogenide section, or selective layer, is with the basis of or made of a material chosen from among the GeSbSe, GeSe, AsSeSiGe, AsSe, SbSe, SiSe, AsTe, SiGeSe, AJTe alloy families, optionally doped with nitrogen N. It is noted that the stoichiometric coefficients between the chemical elements of these alloys can vary, for example, according to the targeted applications.

It is specified that, in the scope of the present invention, the terms “on”, “surmounts”, “covers”, “underlying”, “opposite” and their equivalents do not necessarily mean “in contact with”. Thus, for example, the deposition, the transfer, the bonding, the assembly or the application of a first layer or a second layer, does not compulsorily mean that the two layers are directly in contact with one another, but means that the first layer covers at least partially the second layer, either by being directly in contact with it, or by being separated from it by at least one other layer or at least one other element.

By a parameter “substantially equal to/greater than/less than” a given value, this means that this parameter is equal to/greater than/less than the given value, plus or minus 10% close to this value. By a parameter “substantially between” two given values, this means that this parameter is, as a minimum, equal to the smallest given value, plus or minus 10%, close to this value, and as a maximum, equal to the largest given value, plus or minus 10%, close to this value.

By a substrate, a layer, a zone or a portion “with the basis” of a material A, this means a substrate, a layer, a zone or a portion comprising this material A, for example at a rate of at least 50%, and optionally other materials, for example, doping elements.

In the scope of the invention, the energies are given in electronvolts, for which 1 eV≈1602.10-19J, in the international unit system.

In an absolutely known manner in the field, the chalcogenide family means the chemical elements of the 16^{th} column of the periodic table of chemical elements, or equally, the column preceding those of halogens and noble gases.

In the detailed description below, use can be made of terms such as “horizontal”, “vertical”, “longitudinal”, “transverse”, “upper”, “lower”. These terms must be interpreted relatively in relation to the normal position of the PCM device during its manufacture. For example, the notions “horizontal” and “longitudinal” correspond to the main direction of extension of the layers and sections, and in particular, of the chalcogenide layer(s) and section(s), of the PCM device.

Also, a system will be used, the longitudinal or rear/front direction of which corresponds to the Y axis, the transverse or right/left direction corresponds to the X axis, and the vertical or bottom/top direction corresponds to the Z axis.

The method for manufacturing the PCM device will now be described in reference to the figures according to several examples of embodiments.

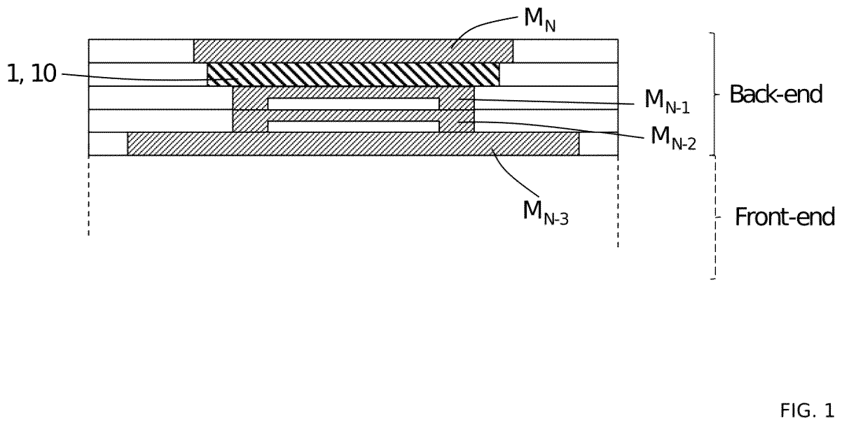

A PCM device 1 is typically manufactured in back-end (of line). The PCM device 1 and its substrate can be disposed between two metal layers M of the back-end, in particular between the two last levels, for example, between MN and MN−1 as illustrated in FIG. 1. The position of the part of the device manufactured in front-end (of line) is indicated by the dotted line in FIG. 1. The integrations can more generally go up to ten metal levels or more. The term “substrate” does not necessarily mean a monolayer and can comprise a stack of layers, in particular, in the scope of a back-end embodiment.

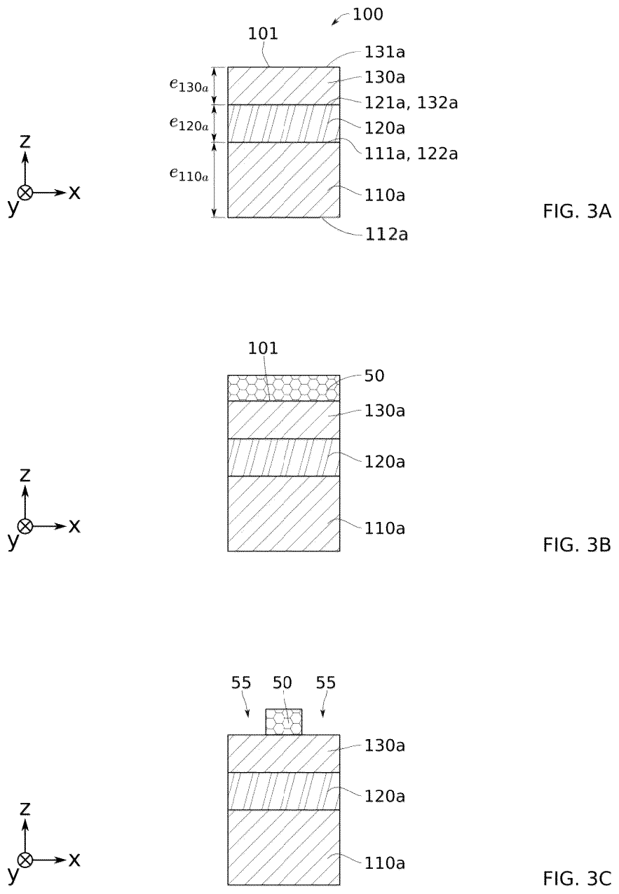

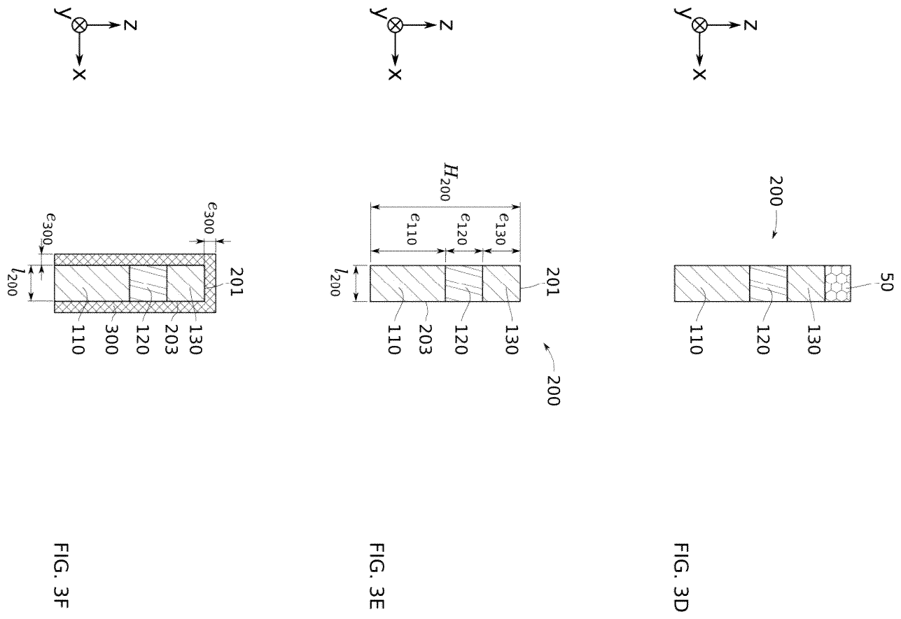

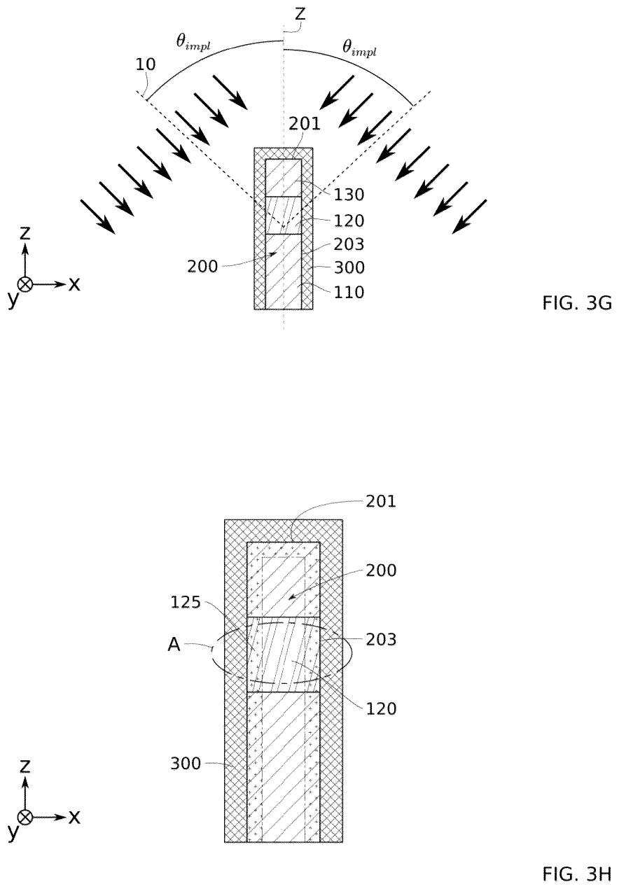

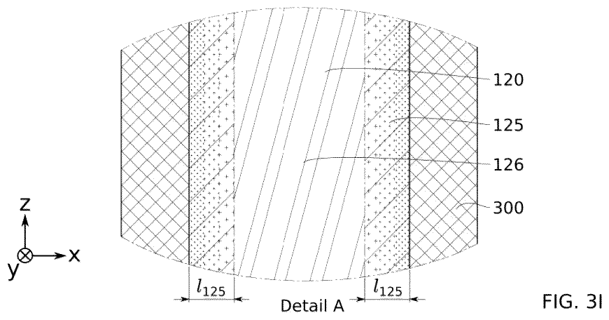

An example of an implementation of the method according to the invention will now be described in reference to FIGS. 3A to 3I.

As illustrated in FIG. 3A, a first step consists of the provision of a stack 100 comprising, stacked in a stack direction Z: a lower layer 110a, a chalcogenide layer 120a and an upper layer 130a. The chalcogenide layer 120a surmounts the upper face 111a of the lower layer 110a. Preferably, the lower face 122a of the chalcogenide layer 120a is in direct contact with the upper face 111a of the lower layer 110a. The upper layer 130a surmounts an upper face 121a of the chalcogenide layer 120a. Preferably, the lower face 132a of the upper layer 130a is in direct contact with the upper face 121a of the chalcogenide layer 120a. Preferably, the upper 111a, 121a, 131a and lower 112a, 122a, 132a faces of the lower 110a, chalcogenide 120a and upper 130a layers extend along planes parallel to a transverse plane XY perpendicular to the stack direction Z.

In the stack direction Z, the lower 110a, chalcogenide 120a and upper 130a layers respectively have thicknesses e₁₁₀ₐ, e₁₂₀ₐ, and e₁₃₀ₐ.

The stack 100 has an upper face 101. Preferably, the upper face 101 of the stack 100 coincides with the upper face 131a of the upper layer 130a.

The chalcogenide layer 120a is with the basis of at least one chemical element of the chalcogenide family.

A second step of the method consists of a patterning etching of the stack 100, so as to form a memory point 200 such as illustrated in FIG. 3E.

The patterning etching can occur according to the steps represented in FIGS. 3B to 3E. Typically, an etching mask 50 is deposited on the upper face 101 of the stack 100 (FIG. 3B). Openings 55 are then formed in the etching mask 50. An etching is then performed in the upper layer 130a, the chalcogenide layer 120a and the lower layer 110a, through openings 55 of the etching mask 50. This etching passes through the upper layer 130a and the chalcogenide layer 120a over all their respective thicknesses e₁₃₀ₐ and e₁₂₀ₐ. The patterning etching can be stopped in the lower layer 110a, or pass fully through the latter. Following the patterning etching, a memory point 200 is obtained, comprising a lower electrode 110 formed in at least one part of the lower layer 110a, a chalcogenide section 120 formed in the chalcogenide layer 120a and an upper electrode 130 formed in the upper layer 130a.

The thicknesses e₁₁₀, e₁₂₀, and e₁₃₀ in the stack direction Z of these electrodes and section are each substantially equal to the thickness e₁₁₀ₐ, e₁₂₀ₐ, e₁₃₀ₐ and e_{120a′}, of the layer from which they have been formed.

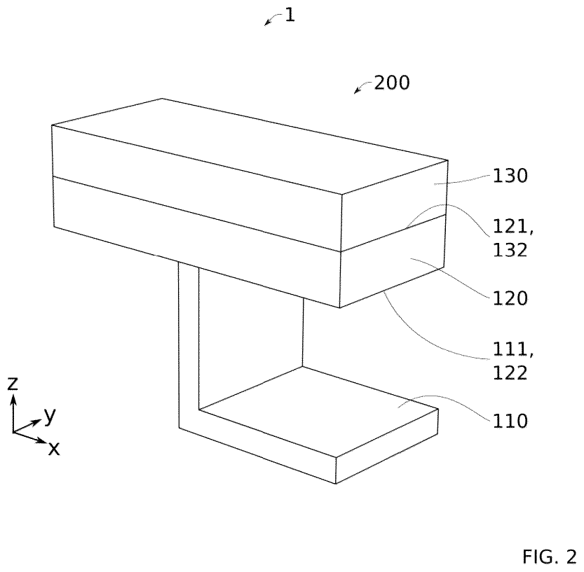

The memory point 200 has an upper face 201 extending substantially into the same plane as the upper face 101 of the stack 100 from which the memory point 200 has been formed. The upper face 201 thus extends preferably into a plane substantially parallel to the transverse plane XY. The memory point 200 also has a side surface 203 extending from its upper face 201 and over its entire height H₂₀₀. The geometry of the side surface of the memory point 200 depends, in particular, on the targeted applications. If the memory point 200 has the shape of a cylinder, its side surface 203 corresponds to the surface defined by the straight lines generating said cylinder and extending over its height H₂₀₀. This is in particular the case when the different sections 110, 120, 130 composing the memory point 200 have the same projection in the transverse plane XY. The side surface 203 of the memory point 200 can also be more complex, in particular, when, like in the example illustrated in FIG. 2, the different sections 110, 120, 130 composing the memory point 200 do not have the same projection in the transverse plane XY. The side surface 203 thus typically comprises a plurality of flanks, each extending mainly in a plane parallel to a plane generated by two of the three X, Y and Z axes.

The memory point moreover has, in any direction of the transverse plane XY, a radial dimension l₂₀₀. l₂₀₀ is typically greater than 10 nm and/or less than 100 nm.

All or only part of the chalcogenide section 120 is configured to change phase during the use of the device 1. It can be specific to passing from an amorphous state to a crystalline state, or vice versa. In particular, the chalcogenide section 120 can be specific to passing from an amorphous state to a crystalline state, or vice versa, when the chalcogenide section 120 is a so-called “memory” layer. The passage between the amorphous state and the crystalline state makes it possible to store a high resistive reset state in the amorphous state or a low resistive set state in the crystalline state in a so-called “memory” layer. The resistivity in the reset state is greater than the resistivity in the set state.

As illustrated in FIGS. 3D to 3I, the chalcogenide section 120 can comprise one single layer, the memory layer, i.e. that there are not two chalcogenide sections separated by a layer other than a chalcogenide section, for example, an electrode. For example, in this case, the device 1 does not comprise a selective layer described below. In this case, preferably, all of the chalcogenide section 120 is configured to change phase during the use of the device. It is also possible that only some of the chalcogenide section 120 is configured to change phase, for example, in the case of a programming in an intermediate state. According to an example, the lower electrode 110 can be an electrode configured to provide the electrical pulse to the chalcogenide section 120 for its passage from one state to the other. The lower electrode 110 can be an electrode referenced by the term of “heater”. Typically, a “heater” electrode has a contact surface with the chalcogenide section 120 reduced with respect to the contact surface between the chalcogenide section 120 and an upper electrode 130. It is noted that it can be provided that the lower electrode 110 has a given geometry, and that the upper electrode 130 has a given geometry, not necessarily separate from one another.

The upper electrode 130 is generally referenced by the term “top electrode”.

Preferably, the etching mask 50 is removed after the patterning etching, as illustrated by the passage from FIG. 3D to FIG. 3E.

Following the patterning etching, the memory point 200 is encapsulated by an encapsulation layer 300. The encapsulation layer 300 is in contact with the upper face 201 of the memory point 200 and with at least one part of its side surface 203, extending from the upper face 201. The encapsulation layer 300 is in contact with the upper face 201 and with the side surface 203 of the memory point 200. Preferably, the encapsulation layer 300 covers all of the side surface 203 of the memory point 200.

The encapsulation layer 300 has a thickness e₃₀₀ deposited conformably over the side surface 203 and the upper face 201 of the memory point 200. The thickness e₃₀₀ of the encapsulation layer 300 is advantageously between 10 and 30 nm, it can be, for example, substantially equal to 20 nm.

The method for manufacturing, according to the invention, the PCM device 1 provides, after the encapsulation of the memory point 200, a step, illustrated in FIG. 3G, of implanting a so-called doping species in the memory point 200 through the encapsulation layer 300. The doping species can be chosen from among carbon, fluorine, nitrogen, indium, arsenic, aluminium, germanium, silicon, chlorine or also boron.

The ion implantation is, for example, done in the reaction chamber of an implantation reactor, for example an ion beam ion implanter.

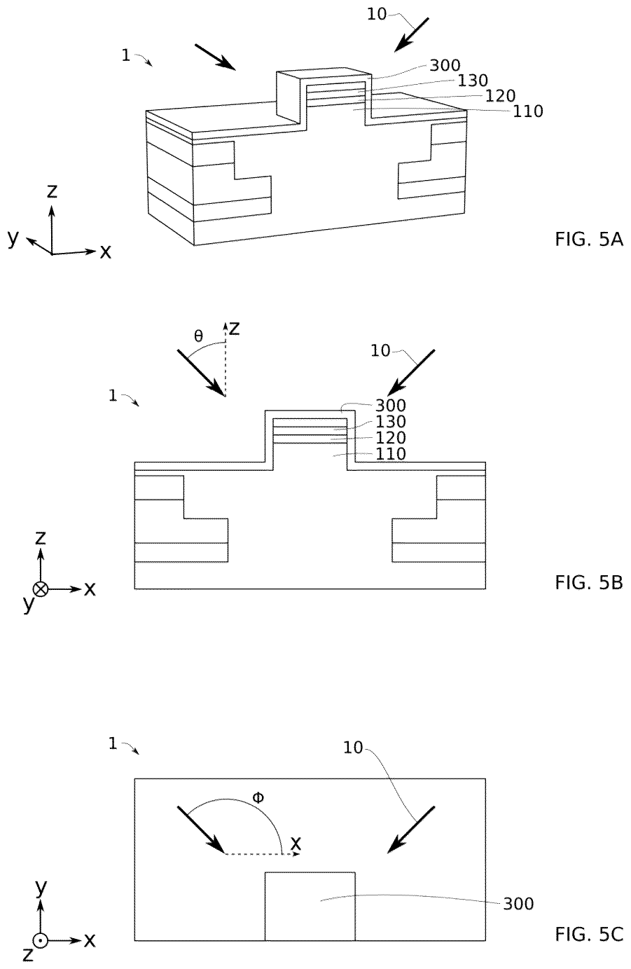

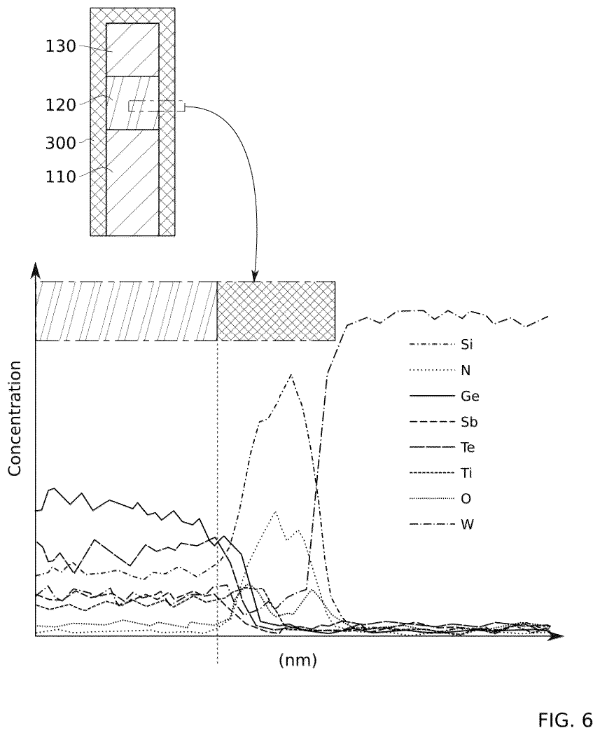

The implantation of the doping species is done in an implantation direction 10 marked in the space by a first angle θ measured with respect to the stack direction Z and by a second angle ϕ measured with respect to the X axis, as illustrated in FIGS. 5B and 5C respectively. A particularity of the invention resides in that the implantation direction 10 forms a so-called non-zero implantation angle θᵢₘₚₗ with the stack direction Z. Preferably, the implantation angle θᵢₘₚₗ is greater than or equal to 20, advantageously greater than or equal to 40°. In this way, the doping species are implanted in the memory point 200, not only from its upper face 201, but also from its side surface 203.

The inclination with respect to the vertical of the implantation direction 10, in particular makes it possible to target the interface between the memory point 200 and the encapsulation layer 300 at the side surface 203 of the memory point 200. Certain current solutions implementing a doping of chalcogenide layers provide a doping by co-sputtering of the chalcogenide species and of the doping element. Such a co-sputtering however does not make it possible to introduce the doping element at the interface between the memory point 200 and the encapsulation layer 300.

The angle ϕ formed by the implantation direction 10 with the X axis is, itself, any. It can in particular be considered that this angle varies during the implantation step, or that the implantation step is carried out for several values of 0. This makes it possible to distribute the implantation better within the memory point 200. This can, in particular, make it possible to perform an implantation from the entire side surface 203 of the memory point 200. The implantation enables the doping in the doping species of at least one portion 125, called doped portion, extending at least into the chalcogenide section 120, from the side face 203. The doped portion 125 is defined as the region of the memory point 200 having, after the implantation step, an atomic concentration of doping species, greater than or equal to 0.5%. Preferably, this atomic concentration is between 0.5% and 5%. The chalcogenide section also comprises a portion 126, called non-doped portion, extending from the doped portion 125 and up to the centre of the chalcogenide section 120. The non-doped portion 126 has a concentration of doping species less than the doped portion 125, even zero. Preferably, the non-doped portion 126 is defined as the region of the memory point 200 having, after the implantation step, an atomic concentration of doping species strictly less than 0.5%.

The doped portion 125 of the chalcogenide section 120 extends preferably along the stack direction Z over at least 50%, and advantageously, at least 75%, of the thickness e₁₂₀ of the chalcogenide section 120. Preferably, the doped portion 125 extends over the entire thickness e₁₂₀ of the chalcogenide section 120. As illustrated in FIG. 3I, the doped portion 125 has, in projection in any direction of the transverse plane XY, a radial dimension 1125. The radial dimension 1125 is advantageously greater than or equal to 2 nm, preferably greater than or equal to 5 nm, over the entire height of the doped portion 125. Preferably, the doped portion 125 extends over at least 20% of l₂₀₀. Moreover, the radial dimension l₁₂₅ is advantageously less than or equal to 20 nm, preferably less than or equal to 10 nm, over the entire height of the doped portion 125. Preferably, the doped portion 125 extends over 80% or less of the radial dimension l₂₀₀ of the memory point 200.

As illustrated in FIG. 3H, the implantation is typically configured such that the doped portion 125 extends not only into the chalcogenide section 120, but also in the lower electrode 110 and/or the upper electrode 130. The doped portion 125 extends typically from the side surface 203 and the upper face 201. Advantageously, it extends in the stack direction Z over at least 50%, and advantageously, at least 75%, of the height H₂₀₀ of the memory point 200. Preferably, the doped portion 125 extends over the entire height H₂₀₀ of the memory point 200.

Different implantation radial profiles can be obtained in the chalcogenide section 120 and more generally, in the memory point 200, thanks to an adjustment of the implantation parameters, in particular, the dose and the implantation energy. These parameters make it possible, in particular, to control the radial dimension 1125.

According to an example, the concentration profile of the doping species in the doped portion 125 is homogenous in the transverse plane XY over all its radial dimension l₁₂₅. Such a profile can, in particular, be obtained by a high-energy implantation, for example, at 30 keV for a carbon implantation. According to an alternative example, it can be provided that the ion implantation step is configured to form a concentration profile of the non-uniform doping species in the transverse plane. For that, the ion implantation step can, for example, comprise several successive ion implantations. In the latter example, in particular, it is preferably considered that the atomic percentage of doping species in the doped portion of a chalcogenide section corresponds to the maximum atomic percentage observed in this given chalcogenide section. The doped portion can, for example, have a gradient of doping species, the maximum value of which corresponds to this maximum atomic percentage observed. The maximum atomic percentage of doping species in the non-doped portion is thus preferably less than or equal to 30%, preferably 20%, even 10% of this maximum value observed in the doped portion. Preferably, in any case, the atomic percentage of doping species in the non-doped portion will be less than a given threshold, for example, 0.5%. The doping profile of doping species can be determined by several methods, such as Raman spectroscopy or X-ray spectroscopy, in particular associated with transmission electron microscopy (TEM).

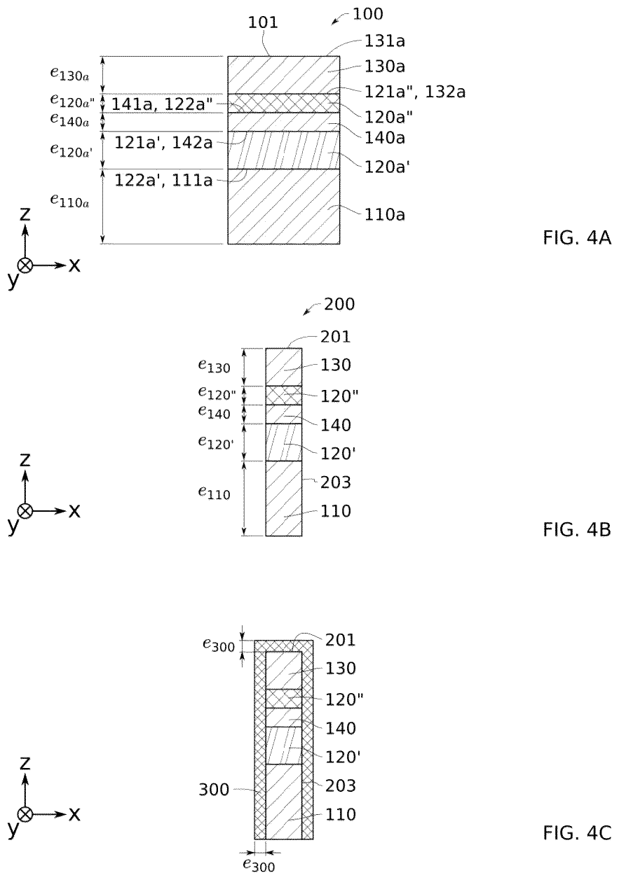

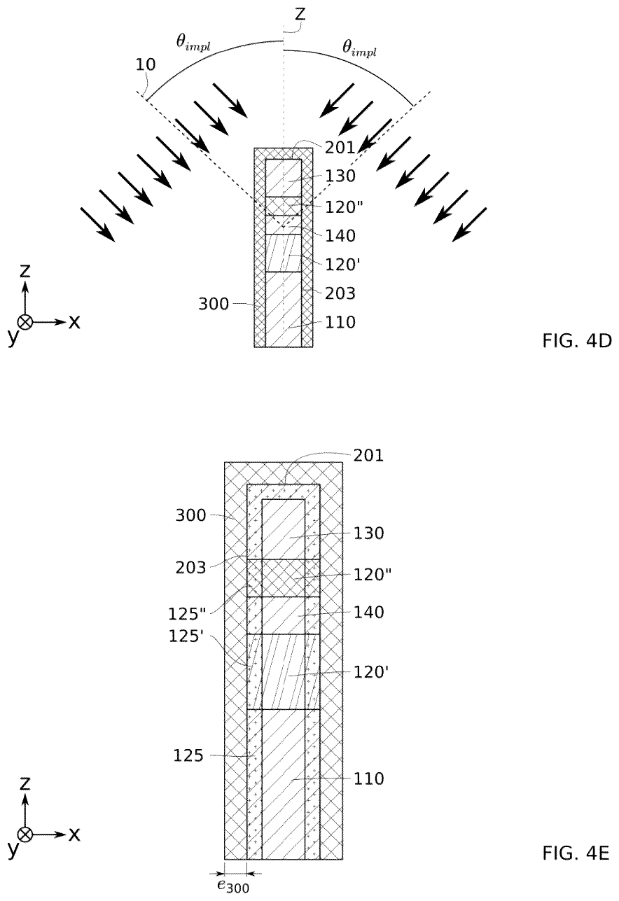

Another example of an implementation of the method according to the invention will now be described in reference to FIGS. 4A to 4E.

In this embodiment, as illustrated in FIG. 4B, the chalcogenide section 120 comprises a first chalcogenide section 120′ and a second chalcogenide section 120″ separated in the stack direction Z by an intermediate electrode 140.

To obtain a memory point 200 having these layers, it is possible to implement the steps described below.

The stack 100 provided initially comprises, according to this example, stacked in a stack direction Z: a lower layer 110a, a first chalcogenide layer 120a′, an intermediate layer 140a, a second chalcogenide layer 120a″ and an upper layer 130a. The chalcogenide layer 120a described in the first embodiment, thus comprises two layers 120a′, 120a″ separated by the intermediate layer 140a.

A patterning etching then makes it possible to obtain the memory point 200. As described in the scope of the first embodiment, this etching is advantageously performed through openings made in an etching mask 50 deposited on the upper face 101 of the stack 100. The patterning etching this time passes through the upper layer 130a, the first chalcogenide layer 120a′, the intermediate layer 140a, the second chalcogenide layer 120a″ over all their respective thicknesses e₁₃₀ₐ, e₁₂₀ₐ, e₁₄₀ₐ and e_{120a′}. The patterning etching can be stopped in the lower layer 110a, or pass fully through the latter.

Following the patterning etching, a memory point 200 is obtained, comprising, stacked in the stack direction Z:
a lower electrode 110 formed in at least one part of the lower layer 110a,
a first chalcogenide section 120′ formed in the first chalcogenide layer 120a′,
an intermediate electrode 140 formed in the intermediate layer 140a,
a second chalcogenide section 120″ formed in the second chalcogenide layer 120a″, and
an upper electrode 130 formed in the upper layer 130a.

The thicknesses e₁₃₀, e_{120″}, e₁₄₀ and e_{120′} in the stack direction Z of these electrodes and sections are each substantially equal to the thickness e_{130A}, e_{120a″}, e₁₄₀ₐ and e_{120a′} of the layer from which they have been formed. The thickness e₁₁₀ of the lower electrode 110 depends on the depth of the etching in the lower layer 110a.

The second chalcogenide section 120″ is commonly called selective layer. The selective layer is preferably intended to remain amorphous.

A layer can be disposed between the second chalcogenide section 120″, or selective layer, and the intermediate electrode 140 and/or the upper electrode 130, for example, a carbon-based layer, configured to block the interdiffusion of chemical elements between these layers.

Like in the first embodiment, the memory point 200 has an upper face 201 and a side surface 203, the features of which described in the scope of the first embodiment are transposed, in this case, mutatis mutandis.

Similarly to what has been described for the first embodiment, the memory point 200 is then encapsulated by an encapsulation layer 300 (FIG. 4C), then is subjected to the implantation of a doping species (FIG. 4D). The features and advantages described in the scope of the first embodiment extend mutatis mutandis in the case where the memory point 200 comprises two chalcogenide sections 120 separated by an intermediate electrode. Advantageously, in this embodiment, the doped portion 125 extends both into the first chalcogenide section 120′ and into the second chalcogenide section 120″. The doped portion 125 thus comprises a first doped portion 125′, extending into the first chalcogenide section 120′, and a second doped portion 125″, extending into the second chalcogenide section 120″.

The first doped portion 125′ of the first chalcogenide section 120′ preferably extends in the stack direction Z over at least 50%, and advantageously, at least 75%, of the thickness e_{120′} of the first chalcogenide section 120. Preferably, the first doped portion 125′ extends over the entire thickness e_{120′} of the first chalcogenide section 120′.

Similarly, the second doped portion 125″ of the second chalcogenide section 120″ preferably extends into the stack direction Z over at least 50%, and advantageously, at least 75%, of the thickness e_{120″} of the second chalcogenide section 120″. Preferably, the second doped portion 125″ extends over the entire thickness e_{120″} of the second chalcogenide section 120′.

The comments developed on the implantation profile fully apply to this embodiment. Below, the advantages of the implantation according to the invention are presented. The advantages described in reference to the chalcogenide section also apply both to the case where the latter comprises a memory layer, and to the case where it comprises both a memory layer and a selective layer. The advantages specific to each of these two scenarios are specifically mentioned.

The implantation step has the consequence of introducing a peak of the concentration of the doping species at the interface between the encapsulation layer 300 and the memory point 200. For example, the atomic concentration of doping species at this interface can reach 5 at. %. The implantation also has the effect of introducing a lateral gradient or any other concentration profile of doping species from the side surface 203 and towards the inside of the memory point 200. This makes it possible to limit the depletion of chalcogenide species that can be observed in FIG. 6, illustrating the development of the concentration of different species in a wafer of a PCM device of the prior art, comprising a portion of the memory layer and of the encapsulation layer. A depletion of Ge is observed in this figure, induced by the oxidation occurring at the venting after etching. An implantation, for example, of carbon, makes it possible to reduce, even prevent the segregation of Ge (or any other chalcogenide species), which is linked to the heterogenous nucleation occurring at the interface between the germanium oxide (GeOx) layer and the chalcogenide material itself. This has the effect of a reduction of the phase separation phenomenon, which can itself cause a reduction of possible elementary depletion phenomena.

This implantation at the interface between the memory point 200 and the encapsulation layer 300 and on the doped portion 125 has the effect of destroying the bonds being formed between the chalcogenide species and oxygen atoms, in particular due to the venting of the memory point between the patterning etching and the encapsulation. Instead of the chalcogenide-oxygen bonds (Ge—O, TeO₂, Sb₂O₃, etc.), bonds are formed between the chalcogenide species and the doping species (Ge—C, Ge—As, etc.). These bonds are, contrary to the oxide bonds, beneficial to the operation of the device 1. They enable, in particular, a phenomenon of passivation of the doped portion 125. This has the advantage of delaying the crystallisation of the regions which are poor in chalcogenide species, typically coinciding with the doped portion 125. The delay to the crystallisation ensures a better uniformity and less variability of the chalcogenide material crystals, while crystals which are coarse and oriented in a non-homogenous manner, typical of non-implanted devices, induce an intrinsic variability.

The implantation also enables a structural relaxation of the material with the basis of the chalcogenide section 120. This has the effect of lowering the density of the PCM device 1, in particular at the interface between the memory point 200 and the encapsulation layer 300.

The presence of the doping species also makes it possible to make the chalcogenide section less impacted by the crystalline segregation between the chemical elements composing it. This has the advantage of making the programming of the SET state reliable. The step of implanting at that part of the upper face 101 and of the side surface 203 of the memory point also makes it possible to improve the property of the interface between the memory point 200 and the encapsulation layer 300. This makes it possible to reduce, even avoid potential interfering effects of degenerating the material constituting the chalcogenide section at the interfaces with the encapsulation layer 300. This also makes it possible to improve the adherence between the memory point 200 and the encapsulation layer 300. The implantation further causes a reduction of the internal stress of the chalcogenide section in its amorphous state, in particular, at its interface with the encapsulation layer 300. This enables a relaxation of the stresses in this region, itself having the benefit of reducing structural defects created in this region, and this, until the end of the integration of the PCM device 1.

The presence of the doping species in the chalcogenide section 120 or memory layer, in particular, in the proximity of the interface with the encapsulation layer 300, makes it possible to improve its thermal performance, in particular, thanks to a reduction of the thermal conductivity. The crystallisation of the chalcogenide species is moreover made more uniform, thanks to this reduction of the thermal conductivity. Indeed, following the emission of an electrical pulse for the programming of the SET state, the heat is discharged more slowly. The process of crystallising the memory layer is therefore improved and made more homogenous. For the memory layer, the variability of the SET state is thus decreased. For the selective layer, the variability of the threshold voltage and the initialisation voltage is decreased.

The different advantages of the implantation described above have general positive consequences on the PCM device:
An improvement of the number of cycles during which the PCM device 1 can operate with greater performance than given specifications. This equals an improvement of the endurance of the device 1.
The fact of achieving performance equivalent to that obtained in the prior art for large dimensions (typically, a width taken along the Y axis of between 50 and 300 nm), this time for reduced dimensions of the memory point 200 (in particular, a width of the memory point taken along the Y axis less than or equal to 50 nm).

It is understood that the advantages described above relative to the implantation step of the method according to the invention naturally extend to the presence of the doped portion 125 in the device according to the invention.

Dimensions of the PCM device 1 are now given as a non-limiting example, in reference to FIGS. 2, 3F and 4C. The PCM device 1 can have a width L, in the direction y substantially between 5 nm and 100 nm. The lower electrode 110 can have a thickness e₁₁₀ substantially of between 30 nm and 200 nm, for example substantially equal to 100 nm. If necessary (FIG. 4C), the intermediate electrode 140 can have a thickness e₁₄₀ substantially of between 2 and 50 nm, for example, substantially equal to 20 nm. The upper electrode 130 can have a thickness e₁₃₀ substantially of between 10 nm and 100 nm, for example, substantially equal to 50 nm. The chalcogenide section (FIG. 3F) can have a thickness substantially of between 10 nm and 100 nm, for example, substantially equal to 50 nm. If necessary (FIG. 4C), the first chalcogenide section 120′ can have a thickness substantially of between 10 nm and 100 nm, for example, substantially equal to 50 nm. If necessary, the first chalcogenide section 120″ can have a thickness substantially of between 5 nm and 50 nm, for example, substantially equal to 25 nm.

### Particular Examples of Embodiments

Results obtained for PCM devices 1 comprising a lower electrode 110, a chalcogenide section or memory layer 110, an upper electrode 120 and an encapsulation layer 300, as, for example, illustrated by FIG. 3F, will now be described. The dimensions of this device 1 correspond to the dimensions described above. In these examples, the memory layer 110 is made of Ge₂Sb₂Te₅, the encapsulation SiN layer and the doping species is carbon.

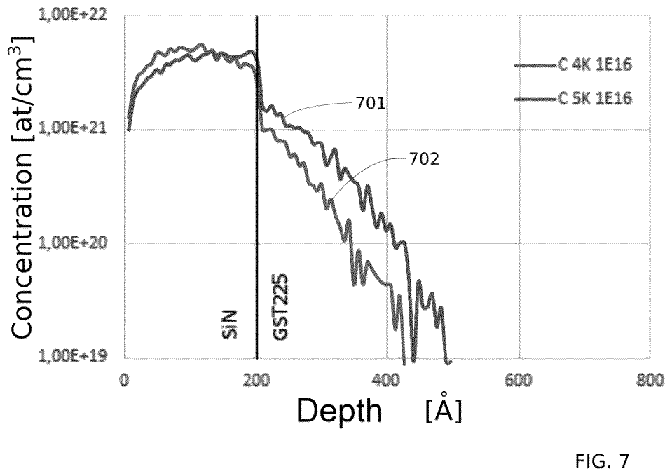

FIG. 7 represents the implantation profiles (concentration in at/cm³) obtained by TRIM simulation for a dose of carbon of 10¹⁶ at/cm² and two distinct implantation energy values (4 keV 701 and 5 keV 702), according to the depth in a wafer of the device 1, extending from the outer flank of the encapsulation layer 300 and up to into the memory layer. For the two implantation energies, a significant carbon density is observed at the interface between the encapsulation SiN layer 300 and the chalcogenide section 120, then that the concentration of carbon in the chalcogenide section 120 decreases with the distance at the PCM/encapsulation interface, over fifteen nanometres. At the interface, the carbon density is around 5 at. %.

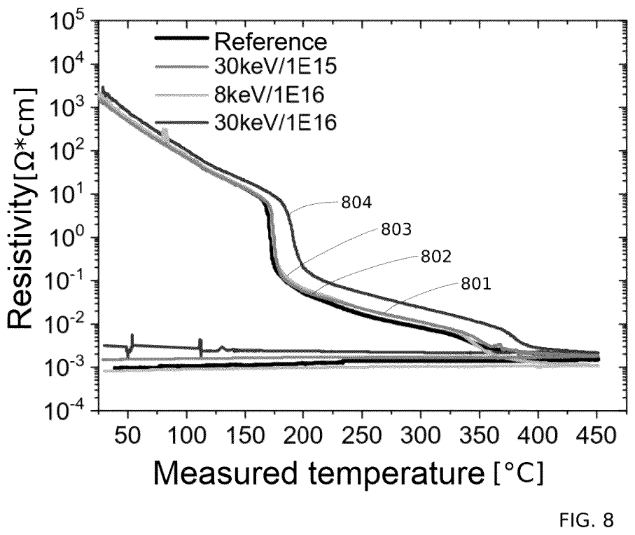

FIG. 8 illustrates resistivity measurements (in Ω·cm) according to the temperature (in ° C.) of amorphous memory layers implanted according to a uniform profile with carbon for different implantation energies (8 keV or 30 keV) and implanted doses (10¹⁵ or 10¹⁶ at/cm²). An increase of the crystallisation temperature is observed for the examples implanted in a greater dose and greater energy. This confirms an improvement of the stability of the amorphous phase with respect to the crystallisation, thanks to the presence of carbon.

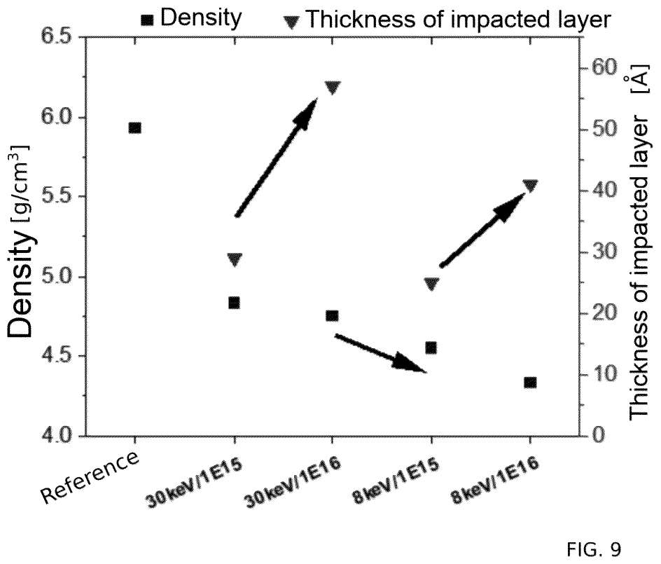

FIG. 9 illustrates density measurements (in g/cm³) and doped or implanted thickness measurements (corresponding to the radial dimension l₁₂₅) (in Å) of amorphous memory layers implanted with carbon for different implantation energies (8 keV or 30 keV) and implanted doses (10¹⁵ or 10¹⁶ at/cm²), as well as a density measurement (in g/cm³) of an non-implanted amorphous memory layer (reference). It is observed that the implantation of carbon makes it possible to reduce, in addition to a unit, the density of the memory layer, whatever the implanted dose and the implantation energy, over a thickness of between 2 nm and 6 nm from the interface with the encapsulation layer 300. The increase of the implanted dose, quite specifically makes it possible to reduce the density. These elements confirm that the implantation enables a structural relaxation and thus, a reduction of the density of the chalcogenide section.

Through the different embodiments described above, it clearly appears that the invention proposes a method for manufacturing a memory device by improving the properties.

The invention is not limited to the embodiments described above, and extends to all the embodiments covered by the invention. In particular, the PCM device can have any feature resulting from the implementation of the method and conversely, the method can comprise any step configured to obtain a feature of the device.

1. A phase change memory device, comprising a stack comprising a memory point comprising, stacked in a vertical direction:
a lower electrode formed in a lower layer;
at least one chalcogenide section formed in at least one chalcogenide layer, disposed on the lower electrode; and
an upper electrode formed in an upper layer and disposed on the at least one chalcogenide section;
wherein the memory point has a side surface and an upper face and further comprises:
an encapsulation layer encapsulating the memory point and disposed in contact with the side surface and with the upper face; and
at least one doped portion, extending from the side surface and inside the chalcogenide section,
wherein the doped portion has a doping with a basis of at least one doping species selected from the group consisting of carbon, fluorine, nitrogen, indium, arsenic, aluminum, germanium, silicon, chlorine, and boron,
wherein the doped portion extends, in the vertical direction (Z), along the entire height of the chalcogenide section,
wherein the chalcogenide section has a non-doped portion having a zero doping, or a doping less than the doping of the doped portion in the doping species, and
wherein the non-doped portion extends from the doped portion and up to a center of the chalcogenide section.

2. The device of claim 1, wherein the doping species of the at least one doped portion has an atomic percentage greater than 0.5%.

3. The device of claim 1, wherein the doped portion has, in all the directions of a transverse plane (XY) perpendicular to the vertical direction (Z), a radial dimension l₁₂₅ with l₁₂₅≤20 nm.

4. The device of claim 1, wherein the doped portion has, in all the directions of a transverse plane (XY) perpendicular to the vertical direction (Z), a radial dimension l₁₂₅ with l₁₂₅≥2 nm.

5. The device of claim 1, wherein the memory point has a height H₂₀₀ in the stack direction, and
wherein the doped portion extends in the stack direction over at least 50% of the height H₂₀₀ of the memory point.

6. The device of claim 1, wherein the encapsulation layer has a thickness e₃₀₀ of between 10 nm and 30 nm.

7. The device of claim 1, wherein the doped portion has a gradient of doping species from its side surface up to the non-doped portion.

8. The device of claim 1, wherein the atomic percentage of the doping species within the doped portion is substantially constant in the stack direction (Z).

9. A method for manufacturing a phase change memory device, the method comprising:
providing a stack having an upper face, the stack comprising, stacked in a so-called vertical direction (Z):
a lower layer;
at least one so-called chalcogenide layer with a basis of at least one chemical element of the chalcogenide family; and
an upper layer;
patterning etching of the stack from its upper face, the patterning etching extending up into at least one part of the lower layer and making it possible to form a memory point comprising:
a lower electrode formed in the lower layer;
at least one so-called chalcogenide section formed in the at least one chalcogenide layer, disposed on the lower electrode; and
an upper electrode formed in the upper layer and disposed on the at least one chalcogenide section, and
wherein the memory point having a side surface and an upper face;
forming an encapsulation layer encapsulating the memory point and disposed in contact with the side surface and with the upper face of the memory point; and
ion implanting a doping species, selected from the group consisting of carbon, fluorine, nitrogen, indium, arsenic, aluminum, germanium, silicon, chlorine, and boron, in the at least one chalcogenide section through the encapsulation layer,
wherein the ion implantation is done in an implantation direction forming an implantation angle θᵢₘₚₗ with the vertical direction (Z), with θᵢₘₚₗ≥25°,
wherein the ion implantation is configured to dope at least one doped portion of the chalcogenide section,
wherein the doped portion extends from the side surface, and to not dope or to dope at a doping less than the doping of the doped portion, a non-doped portion extends from the doped portion and up to a center of the chalcogenide section.

10. The method of claim 9, wherein 20°≤θᵢₘₚₗ≤60°.

11. The method of claim 9, wherein the at least one chalcogenide section comprises a first chalcogenide section and a second chalcogenide section,
wherein the first chalcogenide section is disposed on the lower electrode, and configured to form a memory layer,
wherein the second chalcogenide section is configured to form a selective layer, the second chalcogenide section being separated from the first chalcogenide section by an intermediate electrode, and
wherein the ion implantation is configured such that the portion of the chalcogenide section extends into the first chalcogenide section and the second chalcogenide section.

12. The method of claim 9, wherein during the ion implantation, the implantation energy is greater than or equal to 1 keV.

13. The method of claim 9, wherein during the ion implantation, a dose of doping species Dᵢₘₚ greater than 10¹⁵ atoms/cm² is implanted.

14. The method of claim 9, wherein the encapsulation layer is with a basis of at least one material selected from the group consisting of SiN, SiC, and SiCN.

15. The method of claim 9, wherein the chalcogenide section comprises at least one chemical element selected from the group consisting of germanium, antimony, and tellurium.

16. The method of claim 11, wherein the second chalcogenide section comprises at least one chemical element selected from the group consisting of selenium, arsenic, sulphur, silicon, and aluminum.
